(19) United States
(12) Patent Application Publication
(10) Pub. No.: US 2020/0258838 A1
(43) Pub. Date: Aug. 13, 2020

(54) SYSTEMS AND METHODS FOR SCALE OUT INTEGRATION OF CHIPS

(71) Applicant: Vathys, Inc., Portland, OR (US)

(72) Inventor: Tapabrata GHOSH, Portland, OR (US)

(21) Appl. No.: 16/270,311

(22) Filed: Feb. 7, 2019

(51) Int. Cl. H01L 23/538; H01L 25/00; H01L 25/065

(52) U.S. Cl. CPC H01L 23/5381; H01L 25/0655; H01L 25/50

(57) ABSTRACT

Wafer-scale integration has been a goal of chip manufacturers because of their promise to provide superior computing hardware at lower costs compared to conventional chip manufacturing techniques. Various technical difficulties have made wafer-scale chips impractical or uneconomical to produce. Proposed are systems and methods for achieving wafer-scale integration by utilizing bridge dies to create electrical connections. In one embodiment, semiconductor wafers and printed die grids using standard fabrication (e.g., lithography equipment) can be made into wafer-scale ICs.

### BACKGROUND

### Field of the Invention

This invention relates generally to the field of integrated circuits and more particularly to wafer-scale integrated circuits.

### Description of the Related Art

A semiconductor wafer goes through processing stages where multiple layers are deposited, regions etched and portions are removed or added to pattern an integrated circuit onto the semiconductor wafer. Photolithography techniques are used to deposit material, remove material and otherwise create the layers and connections of a chip on a semiconductor wafer. To make mass-production of chips economical, current chip manufacturing techniques create copies of an integrated circuit (IC) on a semiconductor wafer in a grid-like fashion. Each grid contains a die, which is a small block of semiconductor material on which a given functional circuit is fabricated. No manufacturing process is perfect. After fabricating a grid of ICs on a semiconductor wafer, several dies may be defective. The dies are tested and the defective ones are marked. Subsequently, the dies are cut from the semiconductor wafer and packaged, while defective dies are discarded. The dies may be tested again to discard any more defective batches.

Typically, 30% to 50% of the cost of IC manufacturing can be attributed to the cost of testing and packaging the individual chips produced using the above-described common manufacturing practice. At the same time, the current IC fabrication techniques are made economical when multiple dies are fabricated on a single semiconductor wafer and later cut and packaged. Consequently, a long-time objective of the IC manufacturing industry has been to increase yield while reducing the cost associated with testing and packaging individual dies.

Wafer scale integration (WSI) has been proposed as an alternative. WSI fabrication techniques utilize an entire area of a semiconductor wafer to manufacture a super-chip, an integrated circuit whose circuitry extends to all or a large area of a semiconductor wafer, thereby increasing bandwidth, connectivity and other device performance metrics. WSI chips need not go through semiconductor wafer cutting because the entire pattern printed on the wafer is used as a single circuit with one or multiple interconnected circuits implementing functions and subfunctions. WSI devices also promise to substantially reduce the cost of manufacturing ICs because WSI devices need fewer or no wafer cutting and individual die testing. Additionally, the improved hardware performance metrics promised by WSI devices make them good candidates for complex, voluminous and parallel computing tasks.

However, most attempts to commercialize and manufacture WSI devices have largely been unsuccessful. It is difficult to fabricate a large design printed on a single semiconductor wafer without any flaws. Additionally, most existing and economically viable lithography systems for IC manufacturing (e.g., 193 nm immersion lithography) are designed with limited exposure areas meant for printing copies of small circuit areas on a semiconductor wafer. Optical devices used in lithography equipment have inherent limitations, which make manufacturing at wafer scale level a challenge.

### SUMMARY

In one aspect of the invention, an integrated circuit is disclosed. The integrated circuit includes: at least one semiconductor wafer comprising a plurality of dies; functional circuits embedded in the plurality of dies; and at least one bridge die fabricated on two or more plurality of dies and electrically connecting the functional circuits embedded in the two or more plurality of dies such that the plurality of dies provide computing resources in unison.

In one embodiment, the functional circuits comprise one or more of logic circuits and memory circuits.

In another embodiment, the bridge die comprises circuitry configured to additionally provide computing resources.

In some embodiments, the bridge die comprises a semiconductor wafer.

In one embodiment, the semiconductor wafer comprising the bridge die is in face-to-face, face-to-back, back-to-face, or back-to-back in relation to the semiconductor wafer comprising the plurality of dies and relative to die grids printed on the semiconductor wafers.

In some embodiments, the bridge die is connected to the two or more plurality of dies via one or more of: through-silicon-vias (TSV), micro-bumps, solder-bumps, C4 bumps, inductive coupling, capacitive coupling, optical coupling, face to face bonding, bonded metal links, and face-to-face vias.

In one embodiment, the bridge die and the two or more plurality of dies are aligned with an alignment process comprising one or more of moiré fringe alignment processes, key alignment processes, mechanical groove-based alignment processes, pick and place, IR alignment processes, and dual backside alignment processes.

In some embodiments, the bridge die is mechanically connected to the two or more plurality of dies via one or more of direct bonding, anodic bonding, hybrid bonding, glues, epoxies, resins, benzocyclobutene (DVS-BCB) polymers, and thermocompression bonding.

In one embodiment, the plurality of dies comprise a die grid, wherein each die comprises a logic and/or memory circuitry substantially identical to other dies in the die grid.

In an embodiment, a machine learning microprocessor includes the integrated circuit.

In another embodiment, a three-dimensional integrated circuit includes the integrated circuit.

In another aspect of the invention a method of achieving wafer scale integration in an integrated circuit is disclosed. The method includes: providing a semiconductor wafer; fabricating a die grid on the semiconductor wafer, wherein each die comprises a circuit; and connecting two or more circuits of the die grid with one or more bridge dies such that the dies within the die grid provide computing resources in unison.

In one embodiment, the circuit comprises one or more of logic and memory circuits.

In another embodiment, connecting two or more circuits comprises connecting via one or more of through-silicon-vias (TSV), micro-bumps, solder-bumps, C4 bumps, inductive coupling, capacitive coupling, optical coupling, face to face bonding, bonded metal links, and face-to-face vias.

In some embodiments, connecting comprises mechanically connecting via one or more of: direct bonding, anodic bonding, hybrid bonding, glues, epoxies, resins, benzocyclobutene (DVS-BCB) polymers, and thermocompression bonding.

In one embodiment, the method further includes aligning the bridge die and the two and more circuits via one or more of moiré fringe alignment processes, key alignment processes, mechanical groove-based alignment processes, pick and place, IR alignment processes, and dual backside alignment processes.

In some embodiment, the method further includes: providing one or more additional semiconductor wafers, each semiconductor wafer comprising a die grid and wherein the bridge dies each also comprise semiconductor wafer comprising a grid die.

### BRIEF DESCRIPTION OF THE DRAWINGS

These drawings and the associated description herein are provided to illustrate specific embodiments of the invention and are not intended to be limiting.

FIG. 1 illustrates a WSI chip built using bridge dies according to an embodiment.

FIG. 2 illustrates a WSI chip where an entire semiconductor wafer is utilized as a bridge die according to an embodiment.

FIG. 3 illustrates a WSI chip comprising multiple semiconductor wafers connected using bridge dies according to an embodiment.

### DETAILED DESCRIPTION

The following detailed description of certain embodiments presents various descriptions of specific embodiments of the invention. However, the invention can be embodied in a multitude of different ways as defined and covered by the claims. In this description, reference is made to the drawings where like reference numerals may indicate identical or functionally similar elements.

Unless defined otherwise, all terms used herein have the same meaning as are commonly understood by one of skill in the art to which this invention belongs. All patents, patent applications and publications referred to throughout the disclosure herein are incorporated by reference in their entirety. In the event that there is a plurality of definitions for a term herein, those in this section prevail. When the terms “one”, “a” or “an” are used in the disclosure, they mean “at least one” or “one or more”, unless otherwise indicated.

### Definitions

“die” is a small block of semiconductor material on which a given functional circuit is fabricated.

“bridge die,” according to the described embodiments is a chip, die, substrate or connection means fabricated between one or more die regions or one or more semiconductor wafers in order to provide connections between those die regions and/or the semiconductor wafers.

“scale out integration,” according to the described embodiments, is a method of achieving wafer-scale integration by using one or more bridge dies (e.g., chips, dies, substrates) fabricated to overlap with one or more die areas within a semiconductor wafer to create connections between those die areas.

Using Bridge Dies to Create Electrical Connections Between Dies and/or Wafers

Most challenges of wafer-scale integration are due to inherent limitations in lithographic techniques and the inability of fabrication techniques to create reliable connections between dies printed on a semiconductor wafer. Additionally, current and standard lithographic technology are geared for printing multiple copies of a chip on a semiconductor wafer.

In one embodiment, a scale out integration is proposed where one or more bridge dies can be used to create the necessary connections between dies on a semiconductor wafer, thereby achieving wafer-scale integration. The dies can contain identical, similar or different circuits manufactured and patterned using standard fabrication equipment or specialized WSI fabrication equipment.

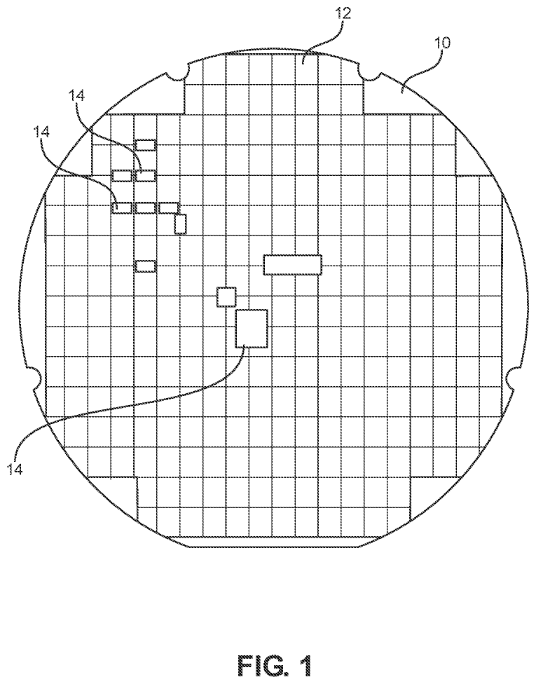

FIG. 1 illustrates a semiconductor wafer 10 and a die grid 12 printed on the semiconductor wafer 10. Die grid 12 can contain identical or diverse ICs implementing one or more memory and/or logical functions as may be used in computing tasks. These functions can include, adder circuits, memory circuits, inverters, multipliers, shifters, “AND,” “OR,” “XOR,” “NOR” circuits and others. In one embodiment, one or more bridge dies 14 can be fabricated on top of the die grid 12 to create connections between dies of the grid 12. Bridge dies 14 can vary in shape, size and numbers depending on the embodiment. In some embodiments, the bridge dies 14 can be used to bypass or rewire defective dies in the die grid 12 and/or create connections between dies on the die grid 12 to allow for integrated circuits with greater computational abilities and bandwidth. For example, bridge dies 14 can be used to connect several memory modules creating a large, high bandwidth and fast memory architecture on the semiconductor wafer 10.

While FIG. 1 illustrates few bridge dies 14 for the purposes of brevity, more bridge dies 14 may be implemented depending on the embodiment. For example, in some embodiments, all die areas may be connected together with the use of bridge dies at all or substantially most abutment points between the dies of the die grid 12. Yet, in other embodiments, not all wafer areas are connected using bridge dies 14 and only some or portions of the die grid 12 may be interconnected using bridge dies 14 to create functional circuits. Depending on the lithography technology used, bridge dies can connect dies or die regions greater in size than the single reticle size. For example, in some lithography technologies, reticle size of 858 mm² is used and consequently, bridge dies can be used to cover and connect any die area larger than or equal to 858 mm². Additionally, when standard lithography techniques are used, bridge dies can increase feature resolution in an area of the die grid 12 where they are deployed.

Some prior efforts to achieve wafer-scale integration have failed due to unavailability or impracticality of fabrication and lithography equipment capable of printing single-design, large circuit areas on a semiconductor wafer. Although, the described embodiments can be effectively used in a single or large-scale chip design, they allow a standard printed semiconductor wafer to achieve wafer-scale integration by externally connecting the multiple dies of the semiconductor wafer and the circuits embedded in them. Therefore, the described embodiments do not require prohibitively expensive or impractical fabrication equipment and high performance, resource-efficient computing systems can be built with the semiconductor wafers retrofitted with the described embodiments using standard lithography techniques.

Additionally, a variety of semiconductor wafers and substrates can be used to implement the semiconductor wafer 10. Examples include a 100 mm circular wafer, 300 mm circular wafer, square wafers, clover-shaped semiconductor wafers and semiconductor wafers of regular or irregular shapes.

A number of communication and power delivery techniques may be used between the bridge dies 14 and die areas within the die grid 12. Examples include, one or some combination of: through-silicon-vias (TSV), micro-bumps, solder-bumps, C4 bumps, inductive coupling, capacitive coupling, optical coupling, face to face bonding, bonded metal links, and face-to-face vias. The communication and power delivery techniques may be the same or can vary between bridge dies 14 and the grid 12 in various wafer regions.

Depending on the embodiment, the bridge dies 14 may be passive (no power required), active, or some combination of the two. Both or only one of active and passive bridge dies may be used on the die grid 12 depending on the logic circuit implemented by the embodiment of FIG. 1. In some embodiments, the bridge dies 14 may be active and also include circuitry to perform computation or they may be passive and provide electrical connection without performing computational tasks.

In other embodiments, more than one layer of bridge die and/or semiconductor wafers can be used to create a three-dimensional integrated circuit configuration.

Various alignment processes can be used to properly align bridge dies 14 with the dies in the die grid 12. Example alignment processes can include, one or more of moiré fringe alignment processes, key alignment processes, mechanical groove-based alignment processes, pick and place, infrared (IR) alignment processes, and dual backside alignment processes.

In some embodiments, one or more mechanical connections between bridge dies 14 and wafer die areas on die grid 12 may be used to secure the bridge dies 14 to the die grid 12. Example mechanical connections include, direct bonding, anodic bonding, hybrid bonding, glues, epoxies, resins, benzocyclobutene (DVS-BCB) polymers, and thermocompression bonding. In other embodiments, mechanical connections between bridge dies and wafer die areas can be omitted.

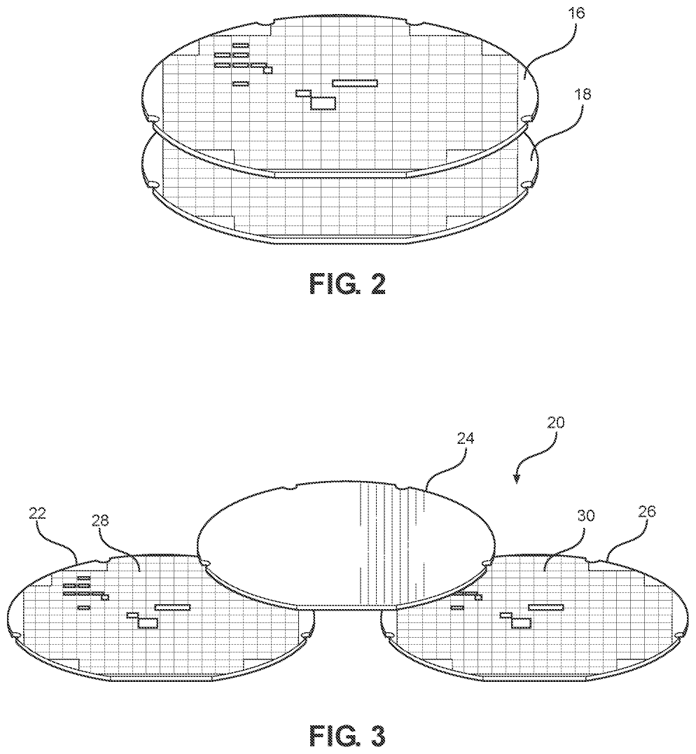

Bridge dies 14 can be as large or as small as needed to implement the circuitry desired. For example, an entire semiconductor wafer can be used as bridge die. FIG. 2 illustrates a semiconductor wafer 18 and a bridge die 16 where an entire semiconductor wafer is dedicated to bridge die 16. One, some, or all dies within the bridge die 16 can be used to provide connections, power and/or computational circuitry to the chips within the semiconductor die 18. Additionally, the bridge die 16 can be perfectly, or near perfectly aligned with the semiconductor wafer 18 or have a vertical and/or horizontal offset with semiconductor wafer 18 in order to line up and connect desired chips between the bridge die 16 and the semiconductor wafer 18.

FIG. 3 illustrates an embodiment of a wafer-scale-integrated IC 20 where bridge dies are used to connect multiple semiconductor wafers. The IC 20 includes semiconductor wafer 22 connected with bridge die 24 to another semiconductor wafer 26. Semiconductor wafer 22 can include a die grid 28 where computational circuits are implemented on a substrate. Semiconductor wafer 26 can include a die grid 30 where additional computational circuits are implemented on a substrate. Bridge die 24 can be connected to the semiconductor wafers 22 and 26 in a face-down configuration with respect to wafers 22 and 26. Bridge die 24 can also include a die grid, which is not visible in the view shown.

While only one bridge die 24 (as a whole wafer bridge die) is shown in FIG. 3, more bridge dies can be used to scale out the IC 20 to larger systems, enabling massive computing systems with large bandwidth and computational circuitry.

While the bridge die 24 is shown in a face-to-face orientation relative to the semiconductor wafers 22 and 26 (and relative to where the die grids 28, 30 and die grid of bridge die 24 are printed), other orientations are also possible. These can include for example, face-to-back, back-to-back and or a combination of them.

Uses

The proposed embodiments allow for the creation of large monolithic computing systems with large high interconnect and memory bandwidth. Such a system is particularly useful for highly parallel computing workloads, such as, but not limited to: machine learning, deep learning, supercomputing, high performance computing (HPC), weather simulations, nuclear simulations, parallel simulations, graph algorithms, and others.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first, second, other and another and the like may be used solely to distinguish one entity or action from another without necessarily requiring or implying any actual such relationship or order between such entities or actions.

The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various implementations. This is for purposes of streamlining the disclosure and is not to be interpreted as reflecting an intention that the claimed implementations require more features than are expressly recited in each claim. Rather, as the following claims reflect, inventive subject matter lies in less than all features of a single disclosed implementation. Thus, the following claims are hereby incorporated into the Detailed Description, with each claim standing on its own as a separately claimed subject matter.

What is claimed is:

1. An integrated circuit, comprising:
at least one semiconductor wafer comprising a plurality of dies;
functional circuits embedded in the plurality of dies; and
at least one bridge die fabricated on two or more plurality of dies and electrically connecting the functional circuits embedded in the two or more plurality of dies such that the plurality of dies provide computing resources in unison.

2. The integrated circuit of claim 1, wherein the functional circuits comprise one or more of logic circuits and memory circuits.

3. The integrated circuit of claim 1, wherein the bridge die comprises circuitry configured to additionally provide computing resources.

4. The integrated circuit of claim 1, wherein the bridge die comprises a semiconductor wafer.

5. The integrated circuit of claim 4, wherein the semiconductor wafer comprising the bridge die is in face-to-face, face-to-back, back-to-face, or back-to-back in relation to the semiconductor wafer comprising the plurality of dies and relative to die grids printed on the semiconductor wafers.

6. The integrated circuit of claim 1, wherein the bridge die is connected to the two or more plurality of dies via one or more of: through-silicon-vias (TSV), micro-bumps, solder-bumps, C4 bumps, inductive coupling, capacitive coupling, optical coupling, face to face bonding, bonded metal links, and face-to-face vias.

7. The integrated circuit of claim 1, wherein the bridge die and the two or more plurality of dies are aligned with an alignment process comprising one or more of moiré fringe alignment processes, key alignment processes, mechanical groove-based alignment processes, pick and place, IR alignment processes, and dual backside alignment processes.

8. The integrated circuit of claim 1, wherein the bridge die is mechanically connected to the two or more plurality of dies via one or more of direct bonding, anodic bonding, hybrid bonding, glues, epoxies, resins, benzocyclobutene (DVS-BCB) polymers, and thermocompression bonding.

9. The integrated circuit of claim 1, wherein the plurality of dies comprise a die grid, wherein each die comprises a logic and/or memory circuitry substantially identical to other dies in the die grid.

10. A machine learning microprocessor comprising the integrated circuit of claim 1.

11. A three-dimensional integrated circuit comprising the integrated circuit of claim 1.

12. A method of achieving wafer scale integration in an integrated circuit, the method comprising:
providing a semiconductor wafer;
fabricating a die grid on the semiconductor wafer, wherein each die comprises a circuit; and
connecting two or more circuits of the die grid with one or more bridge dies such that the dies within the die grid provide computing resources in unison.

13. The method of claim 12 wherein the circuit comprises one or more of logic and memory circuits.

14. The method of claim 12, wherein connecting two or more circuits comprises connecting via one or more of through-silicon-vias (TSV), micro-bumps, solder-bumps, C4 bumps, inductive coupling, capacitive coupling, optical coupling, face to face bonding, bonded metal links, and face-to-face vias.

15. The method of claim 12, wherein connecting comprises mechanically connecting via one or more of: direct bonding, anodic bonding, hybrid bonding, glues, epoxies, resins, benzocyclobutene (DVS-BCB) polymers, and thermocompression bonding.

16. The method of claim 12 further comprising: aligning the bridge die and the two and more circuits via one or more of moiré fringe alignment processes, key alignment processes, mechanical groove-based alignment processes, pick and place, IR alignment processes, and dual backside alignment processes.

17. The method of claim 12, further comprising:
providing one or more additional semiconductor wafers, each semiconductor wafer comprising a die grid and wherein the bridge dies each also comprise semiconductor wafer comprising a grid die.
